(19) United States
(12) Patent Application Publication
(10) Pub. No.: US 2012/0216866 A1
(43) Pub. Date: Aug. 30, 2012

(54) ORGANIC PHOTOVOLTAIC CELL

(76) Inventors: Takehito Kato, Tochigi (JP); Ken Yoshimura, Ibaraki (JP); Toshihiro Ohnishi, Ibaraki (JP)

(21) Appl. No.: 13/503,888

(22) PCT Filed: Oct. 26, 2010
(86) PCT No.: PCT/JP2010/068941

§ 371 Date: Apr. 25, 2012

(30) Foreign Application Priority Data
Oct. 30, 2009 (JP) 2009-250867

(51) Int. Cl. H01L 51/46

(52) U.S. Cl. 136/263

(57) ABSTRACT

An organic photovoltaic cell which comprises an anode, a cathode, and an organic active layer provided between the anode and the cathode. The organic active layer comprises a first electron-donor compound, a second electron-donor compound and an electron-acceptor compound, and the difference between HOMO (highest occupied molecular orbital) energy level of the first electron-donor compound and HOMO (highest occupied molecular orbital) energy level of the second electron-donor compound is 0.20 eV or less. The organic photovoltaic cell has high photovoltaic efficiency.

### TECHNICAL FIELD

The present invention relates to an organic photovoltaic cell used in photovoltaic devices such as solar cells and optical sensors.

### BACKGROUND ART

An organic photovoltaic cell is a cell comprising a pair of electrodes consisting of an anode and a cathode and an organic active layer provided between the pair of electrodes. In an organic photovoltaic cell, one electrode is made of a transparent material. Light is entered from the transparent electrode side and is incident on the organic active layer. The energy (hv) of light incident on the organic active layer generates charges (holes and electrons) in the organic active layer. The generated holes move toward the anode and the electrons move toward the cathode. As a consequence, when an external circuit is connected to the electrodes, current (I) is supplied to the external circuit.

The organic active layer comprises an electron-acceptor compound as an n-type semiconductor material and an electron-donor compound as a p-type semiconductor material. In some cases, the electron-acceptor compound and the electron-donor compound are mixed and used to form an organic active layer of single layer structure. In the other cases, an electron-acceptor layer comprising the electron-acceptor compound and an electron-donor layer comprising the electron-donor compound are joined to form an organic active layer of two-layer structure (see, e.g., Patent Document 1).

Usually, the former organic active layer of single layer structure is referred to as a bulk hetero type organic active layer, and the latter organic active layer of two-layer structure is referred to as a heterojunction type organic active layer.

In the former bulk hetero type organic active layer, the electron-acceptor compound and the electron-donor compound form phases of fine and complicated shapes extending continuously from one electrode to the other electrode side, and form complicated interfaces with being separated from each other. In other words, in the bulk hetero type organic active layer, a phase comprising the electron-acceptor compound and the phase comprising the electron-donor compound are in contact with each other via interfaces of extremely large area. Consequently, an organic photovoltaic cell having the bulk hetero type organic active layer accomplishes a higher photovoltaic efficiency than an organic photovoltaic cell having the heterojunction type organic active layer, in which a layer comprising the electron-acceptor compound and a layer comprising the electron-donor compound are in contact with each other via a single flat interface.

Organic materials used in the organic active layer of the organic photovoltaic cells are organic macromolecular compounds that exhibit a light absorption based on π-π* transition (Patent Document 2). However, in the conventional organic photovoltaic cells, only one type of electron-donor compound is usually used for the organic material that mainly absorbs light in the organic active layer, and its absorption band fails to cover the wavelength range of sunlight available for photovoltaic conversion.

To solve this problem, it has been proposed that two or more types of electron-donor compounds having different absorption wavelengths are used in combination to provide a broader absorption band to cover the usable wavelength range of sunlight (Patent Document 3).

However, according to the combination of two or more types of electron-donor compounds as disclosed in Patent Document 3, an energy transfer from a high-energy excited state to a low-energy state occurs, thus causing insufficient electron transfer to electron-acceptor compounds such as fullerene, or the HOMO (highest occupied molecular orbital) energy levels and LUMO (lowest unoccupied molecular orbital) energy levels of the two or more types of electron-donor compounds used in the combination do not match a suitable arrangement, causing to poor hole transport; as a result, photovoltaic efficiency is not necessarily high.

### RELATED ART DOCUMENTS

### Patent Documents

Patent Document 1: JP 2009-084264 A
Patent Document 2: JP H08-500701 T
Patent Document 3: JP 2005-32793 A

### SUMMARY OF THE INVENTION

The present invention provides an organic photovoltaic cell having high photovoltaic efficiency by selecting plural materials for electron-donor compounds in the organic active layer on the basis of a certain combination criteria. The present invention provides an organic photovoltaic cell having the structure below.

[1] An organic photovoltaic cell comprising:

an anode;

a cathode; and

an organic active layer provided between the anode and the cathode, wherein

the organic active layer comprises a first electron-donor compound, a second electron-donor compound and an electron-acceptor compound, and

the difference between HOMO (highest occupied molecular orbital) energy level of the first electron-donor compound and HOMO (highest occupied molecular orbital) energy level of the second electron-donor compound is 0.20 eV or less.

[2] The organic photovoltaic cell according to [1], wherein the first electron-donor compound is an organic macromolecular compound having at least one of a structural unit indicated by structural formula (1) below and a structural unit indicated by general formula (2) below:

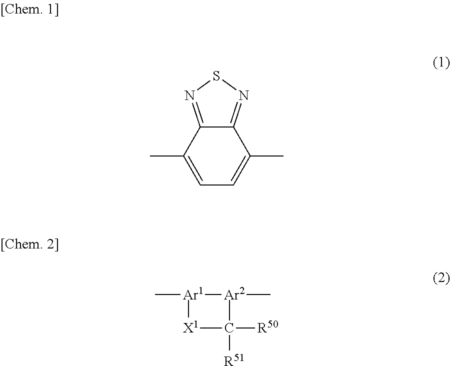

wherein

Ar¹ and Ar², which are the same as or different from each other, represent a trivalent heterocyclic group,

X¹ represents —O—, —S—, —C(═O)—, —S(═O)—, —SO₂—, —Si(R³)(R⁴)—, —N(R⁵)—, —B(R⁶)—, —P(R⁷)— or —P(═O)(R⁸)—,

R³, R⁴, R⁵, R⁶, R⁷ and R⁸, which are the same as or different from each other, represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group,

R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group,

R⁵¹ represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms,

X¹ and Ar² are bonded to adjacent atoms on a heterocycle contained in Ar¹, and

C(R⁵⁰)(R⁵¹) and Ar¹ are bonded to adjacent atoms on a heterocycle contained in Ar².

[3] The organic photovoltaic cell according to [1] or [2], wherein the organic photovoltaic cell has an internal quantum yield of 0.05 or more within an absorption band of the organic active layer ranging from 300 nm to 900 nm.

### EMBODIMENTS FOR CARRYING OUT THE INVENTION

As mentioned above, the organic photovoltaic cell of the present invention comprises an anode, a cathode, and an organic active layer provided between the anode and the cathode, and is characterized in that the organic active layer comprises a first electron-donor compound, a second electron-donor compound and an electron-acceptor compound, and the difference between the HOMO (highest occupied molecular orbital) energy level of the first electron-donor compound and the HOMO (highest occupied molecular orbital) energy level of the second electron-donor compound is 0.20 eV or less.

In the organic photovoltaic cell of the present invention, plural materials having different absorption bands are mixed and used as electron-donor compounds constituting the organic active layer, and the difference between the HOMO energy levels of the materials is set to 0.20 eV or less. This allows the organic photovoltaic cell to absorb light in a broad wavelength band to increase the quantity of light contributing to photovoltaic conversion, leading to improve photovoltaic efficiency.

The components of the organic photovoltaic cell of the present invention, including an anode, an organic active layer, an electron-donor compound and an electron-acceptor compound contained in the organic active layer, a cathode, and other components formed as required will be described in detail below.

(Basic Form of the Photovoltaic Cell)

In a basic form of the photovoltaic cell of the present invention, the photovoltaic cell comprises a pair of electrodes, at least one of which is transparent or translucent, and a bulk hetero type organic active layer formed from an organic composition of electron-donor compounds and an electron-acceptor compound. At least two electron-donor compounds are used to form the organic active layer, and the difference between the HOMO (highest occupied molecular orbital) energy level of a first electron-donor compound and the HOMO (highest occupied molecular orbital) energy level of a second electron-donor compound is set to 0.20 eV or less.

(Basic Action of the Photovoltaic Cell)

The energy of light incident from the transparent or translucent electrode is absorbed by the electron-acceptor compound such as a fullerene derivative and/or the electron-donor compound such as a conjugated macromolecular compound to generate excitons in which electrons and holes are bonded to each other by coulomb coupling. When the generated excitons move and reach a heterojunction interface where the electron-acceptor compound and the electron-donor compound are adjacent to each other, electrons and holes are separated due to a difference in each of HOMO energy and LOMO energy at the interface to generate charges that can move independently (electrons and holes). Each of the generated charges can be extracted outside as electric energy (current) by moving toward the respective electrode. In addition, in the present invention, at least two electron-donor compounds are used to form the organic active layer, and the difference between the HOMO (highest occupied molecular orbital) energy level of a first electron-donor compound and the HOMO (highest occupied molecular orbital) energy level of a second electron-donor compound is set to 0.20 eV or less. In this way, the absorption wavelength range of the organic active layer is widened, and furthermore hole transfer is facilitated.

(Substrate)

The photovoltaic cell of the present invention is usually formed on a substrate. The substrate may be any substrate as long as it does not undergo chemical change when electrodes and an organic layer are formed. Examples of materials for the substrate may include glass, plastic, macromolecular films, and silicon. When an opaque substrate is used, the opposite electrode (i.e., the electrode located farther from the substrate) is preferably transparent or translucent.

(Electrodes)

Materials for the transparent or translucent electrode may include a conductive metal oxide film and a translucent metal thin film. Specifically, a film made of conductive materials such as indium oxide, zinc oxide, tin oxide, and composites thereof, e.g., indium tin oxide (ITO), indium zinc oxide (IZO) and NESA; gold; platinum; silver; and copper are used. Among these electrode materials, ITO, indium zinc oxide, and tin oxide are preferred. Examples of methods for manufacturing electrodes may include a vacuum deposition method, a sputtering method, an ion plating method, and a plating method. For the electrode materials, organic transparent conductive films such as polyaniline and derivatives thereof, and polythiophene and derivatives thereof may also be used.

The other electrode is not necessarily transparent, and electrode materials such as metals and conductive macromolecules may be used for the electrode. Specific examples of materials for the electrode may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; alloys of two or more of these metals; alloys of one or more of these metals and one or more metals selected from the group consisting of gold, silver, platinum, copper, manganese, titanium, cobalt, nickel, tungsten and tin; graphite; graphite intercalation compounds; polyaniline and derivatives thereof; and polythiophene and derivatives thereof. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

(Intermediate Layer)

Additional intermediate layers (such as charge transport layer) other than the organic active layer may be used as a means of improving photovoltaic efficiency. Materials for the intermediate layers may include halides or oxides of alkali metals or alkaline earth metals such as lithium fluoride. Fine particles of inorganic semiconductors such as titanium oxide, and PEDOT (poly-3,4-ethylenedioxythiophene) may also be used.

(Organic Active Layer)

The organic active layer included in the photovoltaic cell of the present invention comprises a first electron-donor compound, a second electron-donor compound and an electron-acceptor compound. The difference between the HOMO (highest occupied molecular orbital) energy level of the first electron-donor compound and the HOMO (highest occupied molecular orbital) energy level of the second electron-donor compound is 0.20 eV or less.

(Electron-Donor Compound: P-Type Semiconductor)

Examples of the electron-donor compound may include p-type semiconducting polymers such as pyrazoline derivatives, arylamine derivatives, stilbene derivatives, triphenyldiamine derivatives, oligothiophene and derivatives thereof, polyvinyl carbazole and derivatives thereof, polysilane and derivatives thereof, polysiloxane derivatives having an aromatic amine in the side chain or main chain thereof, polyaniline and derivatives thereof, polythiophene and derivatives thereof, polypyrrole and derivatives thereof, polyphenylene vinylene and derivatives thereof, and polythienylene vinylene and derivatives thereof.

In addition, an organic macromolecular compound having at least one of a structural unit indicated by structural formula (1) below and a structural unit indicated by general formula (2) below may be mentioned as a suitable p-type semiconducting polymer.

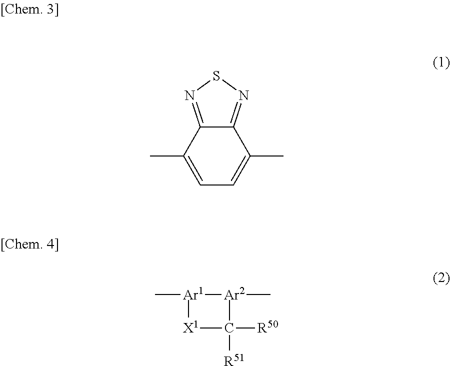

In the formula, Ar¹ and Ar², which are the same as or different from each other, represent a trivalent heterocyclic group; X¹ represents —O—, —S—, —C(═O)—, —S(═O)—, —SO₂—, —Si(R³)(R⁴)—, —N(R⁵)—, —B(R⁶)—, —P(R⁷)— or —P(═O)(R⁸)—; R³, R⁴, R⁵, R⁶, R⁷ and R⁸, which are the same as or different from each other, represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group; R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group; R⁵¹ represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms; and X¹ and Ar² are bonded to adjacent atoms on a heterocycle contained in Ar¹; and C(R⁵⁰)(R⁵¹) and Ar¹ are bonded to adjacent atoms on a heterocycle contained in Ar².

For the organic macromolecular compound, a compound having both of the structural unit indicated by structural formula (1) and the structural unit indicated by general formula (2) is more preferred.

Specific examples of the compound having both of the structural units may include a macromolecular compound A, which is a copolymer of two compounds indicated in structural formula (3) below, and a macromolecular compound B indicated by structural formula (4).

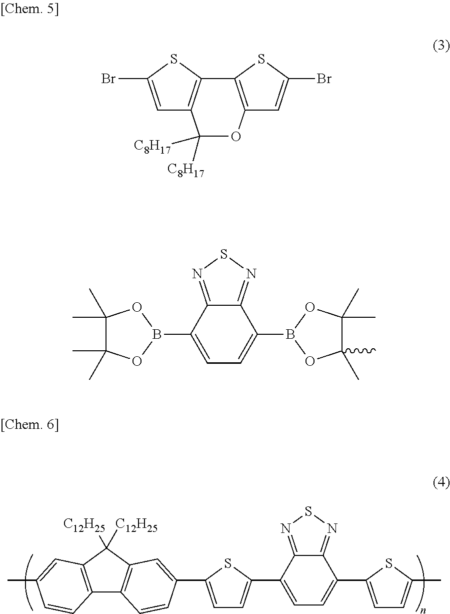

(Electron-Acceptor Compound: N-Type Semiconductor)

Examples of the electron-acceptor compound may include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethyelene and derivatives thereof, diphenoquinone derivatives, metal complexes of 8-hydroxyquinoline and of derivatives thereof, polyquinoline and derivatives thereof, polyquinoxaline and derivatives thereof, polyfluorene and derivatives thereof, fullerenes such as C₆₀ and derivatives thereof, phenanthrene derivatives such as bathocuproine, metal oxides such as titanium oxide, and carbon nanotubes. Preferred electron-acceptor compounds are titanium oxide, carbon nanotubes, fullerene, and fullerene derivatives, and especially preferred electron-acceptor compounds are fullerene and fullerene derivatives.

Examples of the fullerene may include C₆₀ fullerene, C₇₀ fullerene, C₇₆ fullerene, C₇₆ fullerene, and C₈₄ fullerene.

Examples of the fullerene derivatives may include C₆₀ fullerene derivatives, C₇₀ fullerene derivatives, C₇₆ fullerene derivatives, C₇₈ fullerene derivatives, and C₈₄ fullerene derivatives. Specific structures of the fullerene derivatives are as follows.

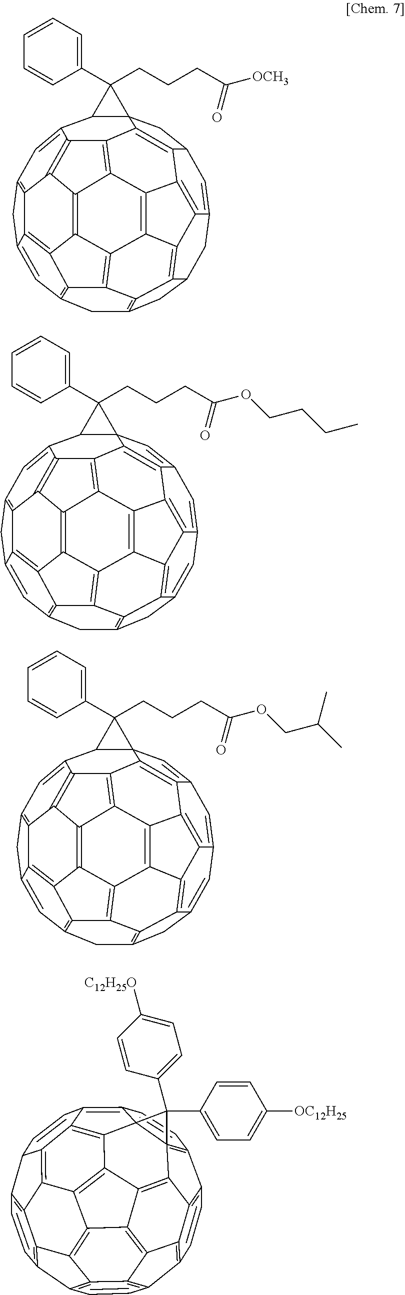

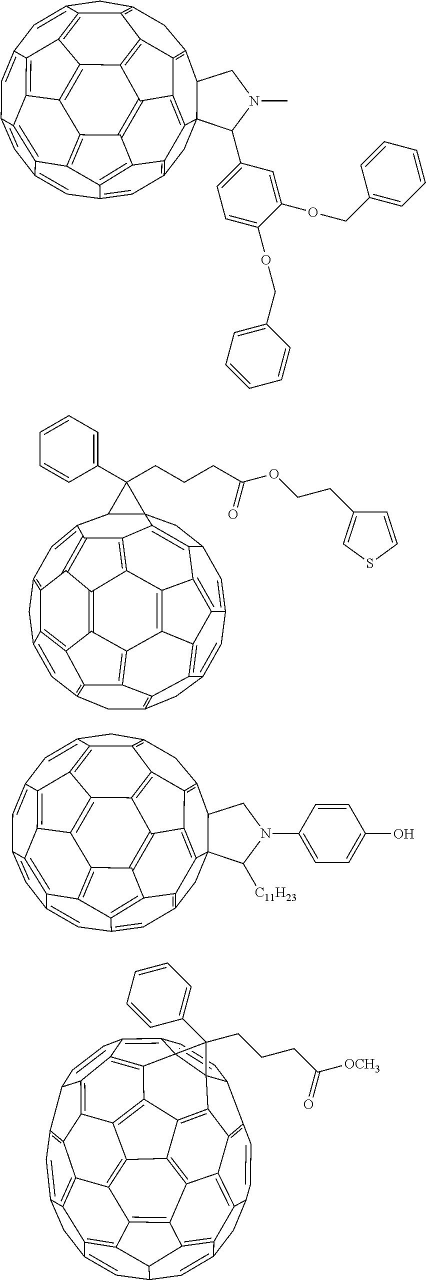

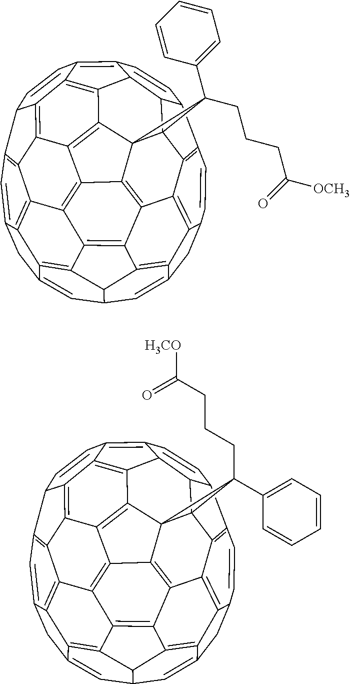

Examples of the fullerene derivatives may include
[6,6]-phenyl C61 butyric acid methyl ester (C60PCBM),
[6,6]-phenyl C71 butyric acid methyl ester (C70PCBM),
[6,6]-phenyl C85 butyric acid methyl ester (C84PCBM), and
[6,6]-thienyl C61 butyric acid methyl ester.

When the fullerene derivative is used as the electron-acceptor compound, the fullerene derivative is used preferably in a ratio of from 10 to 1000 parts by weight, more preferably from 20 to 500 parts by weight, per 100 parts by weight of the electron-donor compound.

Usually, the thickness of the organic active layer is preferably from 1 nm to 100 μm, more preferably from 2 nm to 1000 nm, further preferably from 5 nm to 500 nm, even more preferably from 20 nm to 200 nm.

(Other Components)

The organic active layer may comprise other components, as needed, to exert various functions. Examples of the other components may include an ultraviolet absorbent, an antioxidant, a sensitizer for improving the function to generate charges with absorbed light, and a light stabilizer for improving stability to ultraviolet ray.

It is effective that the components other than the electron-donor compound and electron-acceptor compound are each blended in the organic active layer at a ratio of 5 parts by weight or less, especially from 0.01 to 3 parts by weight, with respect to 100 parts by weight of the total amount of the electron-donor compound and the electron-acceptor compound.

The organic active layer may comprise a macromolecular compound other than the electron-donor compound and electron-acceptor compound of the present invention as a macromolecular binder to improve mechanical properties. For the macromolecular binder, a macromolecular compound that does not inhibit the electron transporting property or the hole transporting property is preferably used, and a macromolecular compound that does not strongly absorb visible light is also preferably used. The macromolecular binders may include poly(N-vinylcarbazole), polyaniline and derivatives thereof, polythiophene and derivatives thereof, poly(p-phenylene vinylene) and derivatives thereof, poly(2,5-thienylene vinylene) and derivatives thereof, polycarbonate, polyacrylate, polymethyl acrylate, polymethyl methacrylate, polystyrene, polyvinyl chloride, and polysiloxane.

(Method for Manufacturing the Organic Active Layer)

In the present invention, the organic active layer is of bulk hetero type and can be formed by film deposition from a solution comprising the electron-donor compound, the electron-acceptor compound, and other components blended as needed.

A solvent used for the film deposition using a solution is not particularly limited as long as the solvent can dissolve the electron-donor compound and the electron-acceptor compound. Examples of the solvent may include unsaturated hydrocarbon solvents such as toluene, xylene, mesitylene, tetralin, decalin, bicyclohexyl, n-butylbenzene, sec-butylbenzene and tert-butylbenzene; halogenated saturated hydrocarbon solvents such as tetrachlorocarbon, chloroform, dichloromethane, dichloroethane, chlorobutane, bromobutane, chloropentane, bromopentane, chlorohexane, bromohexane, chlorocyclohexane and bromocyclohexane; halogenated unsaturated hydrocarbon solvents such as chlorobenzene, dichlorobenzene and trichlorobenzene; and ether solvents such as tetrahydrofuran and tetrahydropyran. Usually, the organic materials for forming the organic active layer can be dissolved in the solvent in an amount of 0.1% by weight or more.

For the film formation, applying methods may be used, such as a spin coating method, a casting method, a micro gravure coating method, a gravure coating method, a bar coating method, a roll coating method, a wire-bar coating method, a dip coating method, a spray coating method, a screen printing method, a gravure printing method, a flexo printing method, an offset printing method, an inkjet printing method, a dispenser printing method, a nozzle coating method, and a capillary coating method. Among the above applying methods, a spin coating method, a flexo printing method, a gravure printing method, an inkjet printing method, and a dispenser printing method are preferred.

(Application of Cells)

The photovoltaic cell of the present invention can be operated as an organic thin film solar cell when it is irradiated with light such as sunlight from transparent or translucent electrode to generate a photovoltaic force between the electrodes. It is also possible to use as an organic thin film solar cell module by integrating a plurality of organic thin film solar cells.

It is also possible to operate as an organic optical sensor when a photocurrent flows by irradiation with light from transparent or translucent electrode in a state where a voltage is applied or not applied between the electrodes. It is possible to use an organic image sensor by integrating a plurality of organic optical sensors.

(Solar Cell Module)

The organic thin film solar cell may basically have a module structure similar to that of a conventional solar cell module. The solar cell module usually has a structure in which cells are formed on a supporting substrate, such as metal, and ceramic, and covered with a filler resin, a protective glass or the like, and thus light is captured from the opposite side of the supporting substrate. The solar cell module may also have a structure in which a transparent material such as a reinforced glass is used as the material of a supporting substrate and cells are formed thereon, and thus light is captured from the side of the transparent supporting substrate. Specifically, known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

In a typical superstraight type or substrate type module, cells are arranged at certain intervals between a pair of supporting substrates. One or both of the supporting substrates are transparent and are subjected to antireflection-treatment. The adjacent cells are connected to each other through wiring such as a metal lead and a flexible wiring, and an current collecting electrode is placed at an external peripheral portion of the module for extracting electric power generated in the cell to the exterior. Between the substrate and the cell, various types of plastic materials such as ethylene vinyl acetate (EVA) may be used in the form of a film or a filler resin in order to protect the cell and to improve the electric current collecting efficiency. When the module is used at a place where its surface needs not to be covered with a hard material, for example, at a place unlikely to suffer from impact from outside, one of the supporting substrates can be omitted by forming a surface protective layer with a transparent plastic film or curing the filler resin to impart a protective function. The periphery of the supporting substrate is fixed with a frame made of metal in a sandwich shape so as to seal the inside and to secure rigidity of the module. A space between the supporting substrate and the frame is sealed with a sealing material. A solar cell can also be formed on a curved surface when a flexible material is used for the cell per se, the supporting substrate, the filler material and the sealing material.

In the case of a solar cell with a flexible substrate such as a polymer film, a cell body can be manufactured by sequentially forming cells while feeding a roll-shaped substrate, cutting into a desired size, and then sealing a peripheral portion with a flexible and moisture-resistant material. It is also possible to employ a module structure called “SCAF” described in Solar Energy Materials and Solar Cells, 48, p. 383-391. Furthermore, a solar cell with a flexible substrate can also be used in a state of being adhesively bonded to a curved glass or the like.

### EXAMPLES

Examples of the present invention will be illustrated below. The following examples are merely exemplary to illustrate the present invention, and not to intend to limit the present invention.

### Example 1

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by B.C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

(Formation of Organic Active Layer)

Next, a solution of the macromolecular compound A represented by structural formula (3) shown below (a first electron-donor compound), poly(3-hexylthiophene) (P3HT) (a second electron-donor compound), and [6,6]-phenyl C61 butyric acid methyl ester ([6,6]-PCBM) which is an electron-acceptor compound in a weight ratio of 2:1:4 in chlorobenzene was prepared.

The resultant solution was applied on the surface of the hole transport layer on the substrate by spin coating and then dried under an N₂ atmosphere. A bulk hetero type organic active layer was thus formed on the hole transport layer.

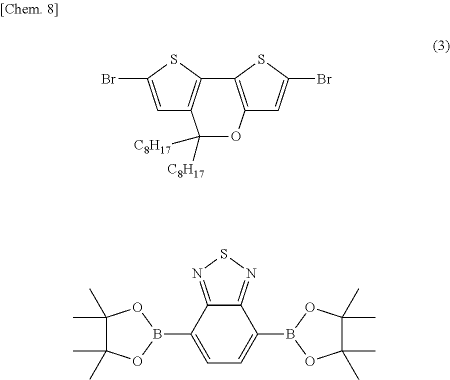

The macromolecular compound A, which is a copolymer of the two compounds indicated in structural formula (3), had a polystyrene-equivalent weight average molecular weight of 17000 and a polystyrene-equivalent number average molecular weight of 5000. The macromolecular compound A had a light absorption edge wavelength of 925 nm. The HOMO energy level of the second electron-donor compound (P3HT) was 5.1, and the HOMO energy level of the first electron-donor compound (macromolecular compound A) was 5.0.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm. The internal quantum yield of the obtained photovoltaic cell was 0.05 or more within a range of 300 nm to 900 nm.

### Example 2

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

(Formation of Organic Active Layer)

Next, a solution of the macromolecular compound B represented by structural formula (4) below (a first electron-donor compound), poly(3-hexylthiophene) (P3HT) (a second electron-donor compound), and [6,6]-phenyl C61 butyric acid methyl ester ([6,6]-PCBM) which is an electron-acceptor compound in a weight ratio of 2:1:4 in chlorobenzene was prepared.

The resultant solution was applied on the surface of the hole transport layer on the substrate by spin coating and then dried under an N₂ atmosphere. A bulk hetero type organic active layer was thus formed on the hole transport layer.

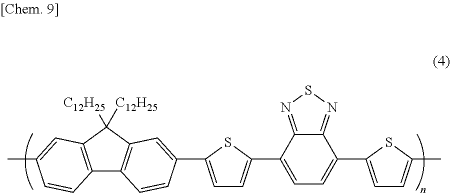

The macromolecular compound A indicated by structural formula (4) above had a polystyrene-equivalent weight average molecular weight of 17887 and a polystyrene-equivalent number average molecular weight of 5000. The macromolecular compound B had a light absorption edge wavelength of 645 nm. The HOMO energy level of the second electron-donor compound (P3HT) was 5.1, and the HOMO energy level of the first electron-donor compound (macromolecular compound B) was 5.3.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm. The internal quantum yield of the obtained photovoltaic cell was 0.05 or more within a range of 300 nm to 900 nm.

### Comparative Example 1

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore diameter of 0.5 micron. The filtrated suspension was applied on the transparent electrode side of the substrate by spin coating to form a film in a thickness of 70 nm. The resultant film was dried on a hot plate at 200° C. for 10 minutes under atmospheric environment, thus forming a hole transport layer on the transparent electrode.

(Formation of Organic Active Layer)

Next, a solution of poly(3-hexylthiophene) (P3HT) (an electron-donor compound) and [6,6]-phenyl C61 butyric acid methyl ester ([6,6]-PCBM) which is an electron-acceptor compound in a weight ratio of 1:0.8 in chlorobenzene was prepared.

The resultant solution was applied on the surface of the hole transport layer on the substrate by spin coating and then dried under an N₂ atmosphere. A bulk hetero type organic active layer was thus formed on the hole transport layer.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

### Comparative Example 2

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore diameter of 0.5 micron. The filtrated suspension was applied on the transparent electrode side of the substrate by spin-coating to form a film in a thickness of 70 nm. The resultant film was dried on a hot plate at 200° C. for 10 minutes under atmospheric environment, thus forming a hole transport layer on the transparent electrode.

(Formation of Organic Active Layer)

Next, a solution of poly(2-methoxy-5-(2′-ethylhexyloxy)-1,4-phenylene vinylene (MEH-PPV) (a first electron-donor compound), poly(3-hexylthiophene) (P3HT) (a second electron-donor compound), and [6,6]-phenyl C61 butyric acid methyl ester ([6,6]-PCBM) which is an electron-acceptor compound in a weight ratio of 2:1:4 in chlorobenzene was prepared.

The resultant solution was applied on the surface of the hole transport layer on the substrate by spin coating and then dried under an N₂ atmosphere. A bulk hetero type organic active layer was thus formed on the hole transport layer.

The HOMO energy level of the second electron-donor compound (P3HT) was 5.1, and the HOMO energy level of the first electron-donor compound was 4.8.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm. The internal quantum yield of the obtained photovoltaic cell was less than 0.05 within a range of 300 nm to 900 nm, which shows that an effective wavelength range for photovoltaic conversion was narrow.

(Evaluation of Photovoltaic Efficiency of Photovoltaic Cells)

The photovoltaic efficiency of the photovoltaic cells obtained in Examples 1 and 2 and Comparative Examples 1 and 2 was evaluated as follows.

The obtained photovoltaic cell (presumed as an organic thin film solar cell: a shape of square measuring 2 mm by 2 mm) was irradiated with a certain amount of light using a solar simulator (manufactured by BUNKOUKEIKI Co., Ltd., under the trade name of “model CEP-2000”, irradiance: 100 mW/cm²) to measure generated current and voltage.

TABLE 1

| | | | Comparative | Comparative |
|---|---|---|---|---|
| | Example 1 | Example 2 | Example 1 | Example 2 |
| Photovoltaic | 1.81 | 0.72 | 0.53 | 0.57 |
| efficiency (%) | | | | |

As shown in Table 1, the photovoltaic cells prepared in Examples 1 and 2 exhibited higher photovoltaic properties than the photovoltaic cells prepared in Comparative Examples 1 and 2.

The organic photovoltaic cell of the present invention can improve photovoltaic efficiency and is useful in photovoltaic devices such as solar cells and optical sensors, and especially suitable for organic solar cells.

1. An organic photovoltaic cell comprising:
a cathode;
an anode; and
an organic active layer provided between the cathode and the anode, wherein
the organic active layer comprises a first electron-donor compound, a second electron-donor compound and an electron-acceptor compound, and
the difference between HOMO (highest occupied molecular orbital) energy level of the first electron-donor compound and HOMO (highest occupied molecular orbital) energy level of the second electron-donor compound is 0.20 eV or less.

2. The organic photovoltaic cell according to claim 1, wherein the first electron-donor compound is an organic macromolecular compound having at least one of a structural unit indicated by structural formula (1) below and a structural unit indicated by general formula (2) below: 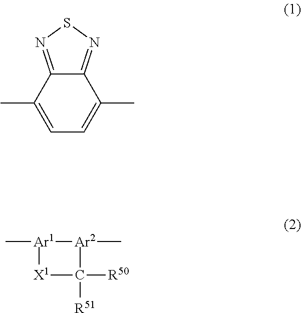
wherein
Ar² and Ar², which are the same as or different from each other, represent a trivalent heterocyclic group,
X¹ represents —O—, —S—, —C(═O)—, —S(═O)—, —SO₂—,
—Si(R³)(R⁴)—, —N(R⁵)—, —B(R⁶)—, —P(R⁷)— or —P(═O)(R⁸)—,
R³, R⁴, R⁵, R⁶, R⁷ and R⁸, which are the same as or different from each other, represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group,
R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group,
R⁵¹ represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms,
X² and Ar² are bonded to adjacent atoms on a heterocycle contained in Ar¹, and
C(R⁵⁰)(R⁵¹) and Ar¹ are bonded to adjacent atoms on a heterocycle contained in Ar².

3. The organic photovoltaic cell according to claim 1, wherein the organic photovoltaic cell has an internal quantum yield of 0.05 or more within an absorption band of the organic active layer ranging from 300 nm to 900 nm.

4. The organic photovoltaic cell according to claim 2, wherein the organic photovoltaic cell has an internal quantum yield of 0.05 or more within an absorption band of the organic active layer ranging from 300 nm to 900 nm.
